(19) United States
(12) Patent Application Publication
(10) Pub. No.: US 2019/0042000 A1
(43) Pub. Date: Feb. 7, 2019

(54) SMART SWITCH

(71) Applicant: Ahmad Kasmieh, Hollis, NH (US)

(72) Inventor: Ahmad Kasmieh, Hollis, NH (US)

(73) Assignee: Nova Forma LLC, Hollis, NH (US)

(21) Appl. No.: 16/077,083

(22) PCT Filed: Feb. 10, 2017
(86) PCT No.: PCT/US17/17434

§ 371 Date: Aug. 10, 2018

Related U.S. Application Data
(60) Provisional application No. 62/294,221, filed on Feb. 11, 2016.

(51) Int. Cl. G06F 3/038; H02J 7/00; H05K 7/14; H05K 1/18; G06F 3/0354; G06F 3/041; G06F 3/0488; G06F 13/40

(52) U.S. Cl. CPC G06F 3/038; H02J 7/0068; H05K 7/1427; H05K 1/181; H05B 33/0854; G06F 3/041; G06F 3/04886; G06F 13/4081; G06F 3/03547

(57) ABSTRACT

Intelligent switches for controlling power delivery to lighting or other circuits are described. The switches may include a touch-control assembly and a microcontroller, and may be programmable to perform a variety of different functions that are useful for residential and commercial electrical circuits. The switches may include interchangeable and upgradable components. The touch-control assembly may be removed from the switch's wall-mount adapter, and may be operated as a remote control, flashlight, or other device.

### BACKGROUND

### Technical Field

The technology relates to intelligent switches that may be used to control lights, outlets, small motors, or other electrical circuits in residential and commercial buildings as well as other settings.

### Discussion of the Related Art

Conventional switches that are used to control AC power delivery to lights or outlets in buildings are typically low-technology devices. Most switches in a building are mechanical toggle-type or push-button switches. Some switches are motion sensitive. Predominantly, conventional switches have one function: turning a light on or off. Dimmer switches are also available for lights, and have an additional function of varying an intensity of a light via a rotatable knob or slider.

### SUMMARY

Smart switches that include a processor and a touch-control assembly are described. A switch of the present embodiments may be programmable and include a plurality of functions in addition to on/off and light-dimming functions. Functionality may be added to a base model of the switch, and parts of the switch (e.g., the touch-control assembly, a cover over a touch-control surface) may be removable and interchangeable.

According to some embodiments, a smart switch may comprise an integrated circuit board, a touch-control assembly having a touch-control surface, a processor, and a wall-mount adapter. The wall-mount adapter may be configured to connect the integrated circuit board and the touch-control assembly to a standard NEMA junction box. In some implementations, the touch-control assembly can be released from the wall-mount adapter and operated, e.g., as a remote control, flashlight, or other device. In some embodiments, the touch-control assembly can be released from the wall-mount adapter and replaced with a different, compatible touch-control assembly to operate the switch without additional replacement of other switch components. For example, the touch-control assembly, and other components of the switch may be interchanged and/or added in a plug-and-play manner.

Some embodiments relate to an intelligent switch for controlling power delivery to at least a first circuit. The switch may comprise an integrated circuit board, a first touch-control assembly having a touch-control surface, a processor, and a wall-mount adapter configured to connect the integrated circuit board and the first touch-control assembly to a junction box in which electrical connection is made to the first circuit, wherein the first touch-control assembly and the wall-mount adapter are configured for plug-and-play interchange of the first touch-control assembly with a different second touch-control assembly. In some aspects, the first touch-control assembly is configured to operate the switch when removed from the wall-mount adapter. In some aspects, a switch further comprises at least one control button located on the integrated circuit board or on the wall-mount adapter configured to operate the switch when the first touch-control assembly is released from the wall-mount adapter. In some aspects, the first touch-control assembly comprises a touch pad and the second touch-control assembly comprises a touch screen.

According to some implementations, the first touch-control assembly and wall-mount adapter provide a waterproof assembly when mounted to the junction box in a wall. The first circuit may be an AC circuit and the first touch-control assembly may be configured to be operated as a switch for at least a second AC circuit in addition to the first circuit when mounted in a same junction box. In some implementations, the first touch-control assembly is further configured to operate as a flashlight.

In some implementations, a switch may further comprise an interchangeable cover that can be mounted over the touch-control surface and removed by a user. In some aspects, a switch may further comprise at least one relay connected to the integrated circuit board, a rechargeable battery arranged to provide power to at least one component of the smart switch, and a charging circuit for the rechargeable battery.

In some aspects, the integrated circuit board includes receptacles for removably plugging in function-adding chips. In some implementations, the integrated circuit board includes receptacles for removably plugging in one or more relays for controlling at least the first circuit. According to some aspects, the touch-control surface comprises a touch pad or a touch screen.

According to some implementations, a switch may further comprise a transceiver for communicating data over a wireless or wired network link. A switch may further include machine-readable instructions that enable the processor to download and install updated versions of machine-readable instructions that control operation of the processor and switch functionality. In some aspects, a switch may further include machine-readable instructions that configure the switch to be controlled remotely by a mobile device, a computer device, and/or a security system.

According to some aspects, a switch may further comprise one or more LEDs mounted in the wall-mount adapter and/or the touch-control assembly. In some cases, a switch may further comprise one or more speakers mounted in the wall-mount adapter and/or the touch-control assembly. A switch may further comprise one or more cameras mounted in the wall-mount adapter and/or the touch-control assembly. In some aspects, a switch may further comprise one or more microphones mounted in the wall-mount adapter and/or the touch-control assembly. In some implementations, a switch may further comprise one or more vibrators mounted in the wall-mount adapter and/or the touch-control assembly.

According to some implementations, a switch may further include machine-readable instructions that adapt the processor to interpret touches or traces made on the touch-control surface as commands to operate the switch. The touch-control surface may be a touch screen and the switch may further include machine-readable instructions that adapt the processor to display artwork on the touch screen. In some cases, a temporary touch of the artwork lasting less than a predetermined time is interpreted by the processor as a command to deliver or terminate power to the first circuit. In some cases, a prolonged touch of the artwork lasting more than a predetermined time is interpreted by the processor as a command to display a context-sensitive menu of operational controls. In some cases, a circular trace made on the artwork is interpreted by the processor as a command to lock or unlock controls of the switch. In some cases, a linear trace made on the artwork in an upward or downward direction is interpreted by the processor as a command to respectively increase or decrease power delivered to the first circuit.

According to some implementations, the touch-control surface is a touch screen and the switch may further include machine-readable instructions that adapt the processor to display a graphical user interface on the touch screen.

In some aspects, a switch may further include machine-readable instructions that adapt the processor to track user interaction with the switch over a period of time and learn the user's behavior and to subsequently execute automated operation of the switch based on the learned user's behavior.

In some aspects, a switch may further comprise a power-measurement circuit and machine-readable instructions configured to detect and report energy consumption of the first circuit.

In some aspects, a switch may further comprise a light sensor and machine-readable instructions to detect ambient light level and increase or decrease power delivered to the circuit to maintain a user-defined level of ambient light.

In some aspects, a switch may further include machine-readable instructions that adapt the processor to detect an alert condition and transmit an alert signal that identifies the alert condition to a server or directly to a mobile device.

In some implementations, a switch may further include machine-readable instructions that adapt the processor to display a graphical user interface that allows a user to group operation of plural smart switches in a local area network.

The foregoing apparatus and method embodiments may be included in any suitable combination with aspects, features, and acts described above or in further detail below. These and other aspects, embodiments, and features of the present teachings can be more fully understood from the following description in conjunction with the accompanying drawings.

### BRIEF DESCRIPTION OF THE DRAWINGS

The skilled artisan will understand that the figures, described herein, are for illustration purposes only. It is to be understood that in some instances various aspects of the embodiments may be shown exaggerated or enlarged to facilitate an understanding of the embodiments. The drawings are not necessarily to scale, emphasis instead being placed upon illustrating the principles of the teachings. In the drawings, like reference characters generally refer to like features, functionally similar and/or structurally similar elements throughout the various figures.

When referring to the drawings in the following detailed description, spatial references “top,” “bottom,” “upper,” “lower,” “vertical,” “horizontal,” “above,” “below” and the like may be used. Such references are used for teaching purposes, and are not intended as absolute references for embodied devices. An embodied device may be oriented spatially in any suitable manner that may be different from the orientations shown in the drawings. The drawings are not intended to limit the scope of the present teachings in any way.

FIG. 1 depicts a perspective view of a smart switch mounted on a wall, according to some embodiments;

FIG. 2A is a cut view that depicts some components of a smart switch, according to some embodiments;

FIG. 2B is a cut view that depicts some components of a smart switch, according to some embodiments;

FIG. 2C depicts circuitry for a smart switch, according to some embodiments;

FIG. 3 depicts an integrated circuit board of a smart switch into which interchangeable function-adding chips may be plugged and removed, according to some embodiments;

FIG. 4A depicts artwork displayed on a touch screen of a smart switch, according to some embodiments;

FIG. 4B depicts a user touch on artwork, which may be interpreted by a smart switch as a command, according to some embodiments;

FIG. 4C depicts a user trace on artwork, which may be interpreted by a smart switch as a command, according to some embodiments;

FIG. 4D depicts a GUI menu for operational controls displayed by a smart switch, according to some embodiments;

FIG. 4E depicts a GUI displayed by a smart switch for granular dimming/stepping control, according to some embodiments;

FIG. 5 depicts a touch pad that includes lights and speakers, according to some embodiments;

FIG. 6A depicts a perspective view of a smart switch mounted on a wall that includes child-proof release buttons, according to some embodiments;

FIG. 6B depicts a perspective view of a smart switch mounted on a wall with a touch-pad plugged in, according to some embodiments;

FIG. 6C depicts a perspective view of a smart switch mounted on a wall with a touch screen plugged in, according to some embodiments;

FIG. 7A depicts a perspective view of a smart switch mounted on a wall that includes finger pull recess to remove an embedded screen remote control that attaches to a wall-mount adapter based on magnetic attachment, according to some embodiments;

FIG. 7B depicts a perspective view of a smart switch mounted on a wall and its screen remote control detached from the wall-mount adapter, according to some embodiments;

FIG. 7C depicts a perspective view of the detached screen remote control that has smooth and curved surface designed for hand holding, and a pin connector for charging, according to some embodiments;

FIG. 8 is a plan view depicting a smart switch with status indicators and a touch pad, according to some embodiments;

FIG. 9A is a plan view depicting a smart switch with status indicators and an exposed touch pad wherein an interchangeable cover may be placed over the touch pad, according to some embodiments;

FIG. 9B is an elevation view (looking from an end) of the smart switch depicted in FIG. 9A; and

FIG. 9C is a plan view of the smart switch depicted in FIG. 9A with an interchangeable cover placed over the touch pad, according to some embodiments.

Features and advantages of the illustrated embodiments will become more apparent from the detailed description set forth below when taken in conjunction with the drawings.

### DETAILED DESCRIPTION

The inventor has recognized and appreciated that household and commercial switches for controlling lighting, outlets, appliances, and other electrical circuits in buildings may benefit from adding data processors (e.g., microprocessors or microcontrollers) to the switches. A processor and machine-readable instructions may greatly expand the functionality of a switch beyond conventional on/off, dimming, and timing functions. The inventor has also recognized and appreciated that a business challenge exists for “smart switches.” A smart switch should provide advanced functionality desired by a consumer and that may be personalized by the user, but should not be exceedingly high in cost beyond conventional switches that offer conventional functionality (e.g., on/off, dimming, and timing). According to some embodiments, a smart switch may be reconfigurable to address changing demands and likes of consumers. For example, a smart switch may include reconfigurable hardware and software components that can be configured to alter or add functionality to the switch, whereas a conventional switch is rigid and requires complete replacement when a different or additional function is needed such as a dimmer, timer, etc.

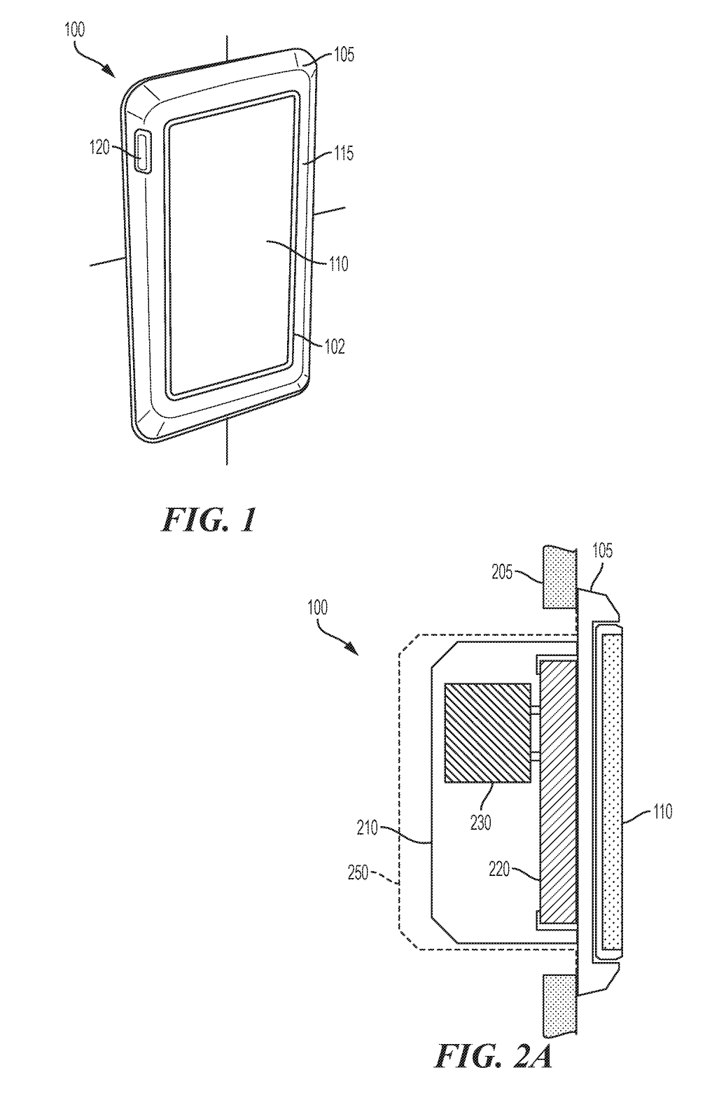

According to some embodiments, a smart switch may comprise a device that includes interchangeable, upgradeable, and removable components that can be added or removed easily by a user without the need to hire an electrician. A smart switch 100 may be mounted to existing residential or commercial junction boxes and appear as depicted in FIG. 1. Features of a smart switch 100 that are visible to a user when installed may include a wall-mount adapter 105 and a touch-control assembly 102 mounted on the wall-mount adapter. The touch-control assembly 102 may comprise a touch-control surface 110 and touch-control casing 115. Other visible elements may include one or more mechanical buttons 120. Additional features described below may be visible in other embodiments.

A consumer may purchase a base model of a smart switch 100 at a cost that provides some functionality beyond on/off and dimming operation. For example, a base model of a smart switch may include a touch pad as the touch-control surface 110, and include on/off, dimming, light timing, and emergency lighting functionality. The touch pad may comprise a capacitive touch pad, a pressure sensitive touch pad, or any other suitable touch-sensitive control surface. Other components and machine-readable instructions may be added to, or interchanged with their counterparts on, a smart switch 100 to provide additional functionality. For example, the touch pad may be interchanged with a touch screen at a later time, and machine-readable instructions may be added at any time to provide additional functionality such as, but not limited to, a native on-switch user interface to set up and operate the switch, configurable background images, nightlight functionality, emergency lighting and/or signaling, multi-switch ambient lighting themes, room-to-room intercom, room-monitor, remote control, voice recognition, internet access, energy-saving functionality, security, fire alarm, CO alarm, music, etc. In some implementations, machine-readable instructions may be offered for free, rented for a period of time, or purchased for perpetual use via an on-line service provider. In this way, a consumer may obtain a base model of a smart switch at a modest price that includes useful functionality, and later upgrade the switch hardware and software components as desired.

In further detail, a smart switch 100 may mount in conventional electrical junction boxes and comply with one or more National Electrical Manufacturers Association (NEMA) standards. In some embodiments, a portion of the smart switch visible to a user may provide a waterproof or water-resistant assembly (sealed against a wall or other surface) that may be mounted in bathrooms, kitchens, outdoors or in a marine environment. For example, the wall-mount adapter 105 may include or mount against an elastomeric seal (not shown) to form a waterproof or water-resistant seal against a wall. Similarly, the touch-control assembly 102 may include or mount against an elastomeric seal (not shown) to form a waterproof or water resistant seal against the wall-mount adapter 105. A waterproof or water-resistant assembly may prevent or reduce ingress of water into the junction box. In some cases, a waterproof assembly may not be needed for some interior applications.

A touch-control surface 110 may comprise a touch pad or a touch screen. For example, a touch pad may comprise a capacitive-sensing surface (or other touch-sensitive surface) that is configured to detect a touch of or close proximity of a user's finger or fingers to the surface of the touch pad. A touch pad may not be capable of displaying an electronic image, in some embodiments. In other embodiments, a touch pad may be configured to display alphanumeric figures and/or icons. A touch screen may comprise a touch-sensitive surface as well as a liquid-crystal or other display that is capable of displaying electronic images, which may include text, as well as a graphical user interface. Touch and/or trace patterns provided to the touch-control surface 110 of a touch-control assembly 102 may be detected by a processor of the smart switch 100 and interpreted as a command to operate the smart switch.

According to some embodiments, a touch-control assembly 102 may be readily removed from the wall-mount adapter 105, and operated when removed from the wall-mount adapter. When removed from the wall-mount adapter, the touch-control assembly may be operated, for example, as a flashlight, a remote control, and/or a room-to-room intercom. In some cases, a touch-control assembly may be operated to view email, to gain Internet access, or for other remote communications when removed from the wall-mount adapter 105. A touch-control assembly 102 comprising a touch pad may be interchangeable with a touch-control assembly comprising a touch screen to operate a smart switch, and vice versa, so that a user may interchange touch pad assemblies and one or more touch-screen assemblies within a building, e.g., to change control features for different circuits within the building. Such interchange may be done in a plug-and-play manner, without requiring, rewiring of the switchbox, new construction, or other hardware modification to the smart switch. According to some embodiments, a user may configure software features in a smart switch to adapt a newly installed touch-control assembly.

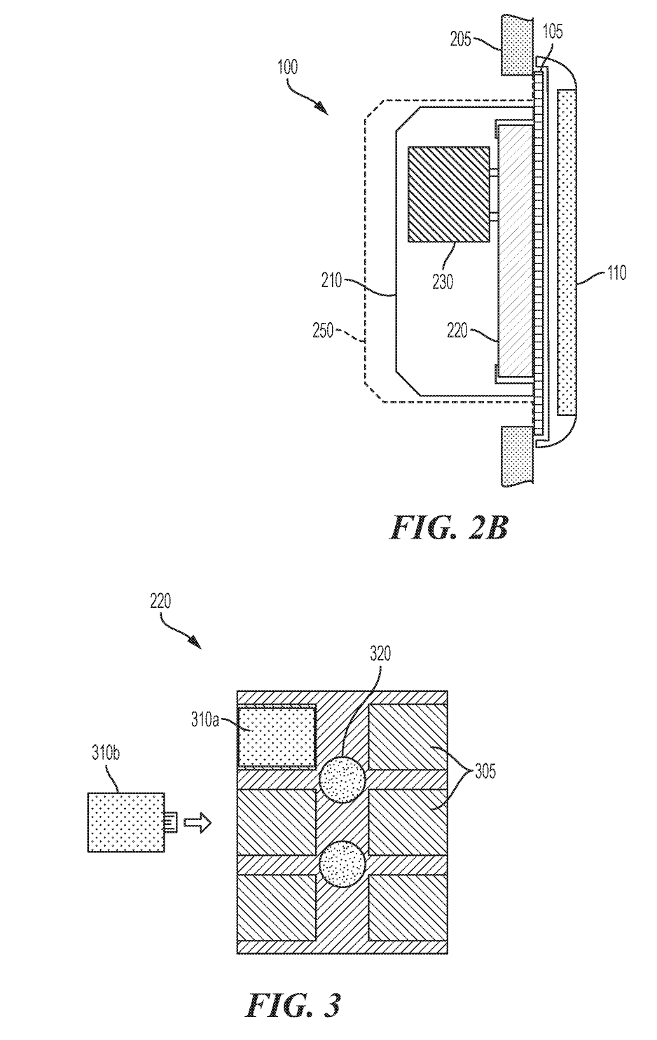

In some embodiments, a touch-control assembly 102 may set into and be retained securely by the wall-mount adapter 105, as depicted in FIG. 2A. For example, the touch-control assembly may be retained by magnets, spring clips, or other retaining elements (not shown). The touch-control assembly 102 may make electrical contact and communicate with electronics behind the touch-control assembly when placed in the wall-mount adapter (e.g., communicate via a multi-pin connector). In some embodiments, the touch-control assembly 102 is larger in size than the opening of a single-gang junction box that is commonly used for conventional lighting switches and outlets (typically about 2 inches by 4 inches). Accordingly, the wall-mount adapter 105 and the touch-control assembly 102 may extend beyond the edges of a single-gang junction box when mounted over the junction box. In other embodiments, a wall-mount adapter 105 may be larger in size, so that it can cover and mount to larger junction boxes (e.g., junction boxes that accommodate multiple conventional switches). In some implementations, the touch-control assembly 102 may extend beyond the periphery of the wall-mount adapter 105 and fasten over the wall-mount adapter, as depicted in FIG. 2B.

The touch-control casing 115 may hold the touch-control surface 110 and electronics associated with the touch-control assembly 102. Electronics housed within the touch-control assembly 102 may include a processor, a battery, and a charging circuit for the battery. The battery may allow the touch-control assembly to be operated when removed from the wall-mount adapter or during a line power outage. In some embodiments, a charging circuit for the battery may be located on an integrated circuit board 220 (shown in FIG. 2A) that is mounted behind the touch-control assembly, and not included in the touch-control assembly. A touch-control assembly 102 may include a processor and digital memory in communication with the processor, according to some embodiments. A processor may comprise a microcontroller, one or more field programmable gate arrays, logic circuitry, a microprocessor, or a combination thereof.

A smart switch 100 may further include one or more mechanical buttons 120 that are visible to a user. In some embodiments, one or more buttons 120 may be used to release the touch-control assembly 102 from the wall-mount adapter 105. (For example, two or three buttons may be distributed on the wall-mount adapter 105 and simultaneous pressing of the buttons may be required to release the wall-mount assembly, so that young children may not readily remove the assembly 102.) In some cases, a button 120 may be electro-mechanical and configured to power up or power down the touch-control assembly. A button 120 may be part of the touch-control assembly, or may be located on the mall-mount adapter 105.

Referring again to FIG. 2A and FIG. 2B, additional components of a smart switch 100 may be mounted within a junction box 250 (depicted by the dashed line) behind the touch-control assembly. According to some embodiments, an integrated circuit board 220 may be securely mounted on the wall-mount adapter 105. The integrated circuit board 220 may comprise one or more printed circuit boards (PCBs) and include electrical components such as resistors, capacitors, diodes, transistors, transformers, rectifying circuits, or other components that may be used for operation of the smart switch 100. In some cases, a processor (not shown) may be mounted on the integrated circuit board 220. A rechargeable battery (not shown) may also be mounted on the integrated circuit board 220 to provide some operation of the smart switch 100 during a power outage (e.g., emergency lighting, audio alarm, network access, etc.).

According to some embodiments, one or more semiconductor devices for controlling electrical circuits of various power ratings such as relays, thyristors, or triode for alternating current (TRIAC) 230, referred to herein as “relays,” may be mounted to the integrated circuit board 220, and used to control power delivery to one or more AC or DC circuits within the building. A relay may have receptacles (not shown) for attaching wires from a circuit to be controlled, or have wires (not shown) that connect to a circuit to be controlled. In some embodiments, a first relay 230 may receive control signals from a processor of the smart switch 100 and control power delivery to lighting in a room of a building according to the received control signals. In some cases, a second relay (not shown) may be included in the same junction box and used to control power delivery to one or more outlets in a room of the building, or other lighting in the room, for example. When multiple relays 230 are used within a junction box, the relays may be of a same or different size and controlled by the same smart switch. Further, the relays may have different specifications. For example, a first relays may have a maximum power rating of 120 volts and 15 amps and a second relay may have a maximum rating of 240 volts and 30 amps.

A relay 230, or relays, may be activated or deactivated in response to commands input to the touch-control assembly 102. The activation and deactivation controls power delivery to a corresponding AC or DC circuit to which each relay is connected. Any commands input by a user to the touch-control assembly may be detected by one or more processors of the smart switch, and used to identify a command that is issued to the one or more relays 230. For example, a touch or trace applied to the touch-control surface 110 may generate electronic signals that are detected and analyzed by a processor of the smart switch 100 to identify a corresponding command (e.g., from a look-up table). The processor may then issue the identified command(s) to the one or more relays 230 to control lighting, motor, or appliance operation.

According to some embodiments, a wall-mount adapter 105 may include an enclosed rear housing 210 that is an integral part of the wall-mount adapter. For example the wall-mount adapter may be formed by an injection-molding process that includes forming the rear housing 210 as part of the wall-mount adapter 105. In some implementations, an enclosed rear housing 210 may not be present. Instead, the wall-mount adapter 105 may be open behind the location where the integrated circuit board 220 is mounted. A wall-mount adapter 105 may include features to mount and retain the integrated circuit board 220, such as threaded holes for screws or snaps into which an integrated circuit board may be pressed and retained. A wall-mount adapter 105 may further include holes for screwing the wall-mount adapter to threaded holes in a junction box 250 that are typically located at the top and bottom of the junction box and used to mount switch plates.

According to some embodiments, a single touch-control assembly 102 may be used to provide switching and other controls for multiple switches when used in larger junction boxes. In some cases, a touch-control assembly 102 may detect the number N of relays mounted on the integrated circuit board 220 and contained within a junction box, and determine that it must provide power-control functionality for N electrical circuits. The touch-control assembly may then automatically configure itself to operate the N electrical circuits. For example, a microprocessor connected to a touch-control surface 110 may be configured to sense N electrical circuits to be controlled by the smart switch and partition the touch-control surface into N areas, wherein a touch or trace input provided to one of the N areas is detected and analyzed to identify a command for one of the N circuits associated with that area of the touch-control surface. The sensing of N controllable circuits may be done by reading a memory element on the integrated circuit board 220 or receiving a signal from sensor circuitry on the integrated circuit board 220 that indicates a number of relays 230 attached to the circuit board 220. In some cases, a touch-screen of the touch-control surface 110 may be partitioned to provide N selectable graphical-user interfaces for operating each of the N circuits. The N selectable graphical-user interfaces may be tiled on the touch-screen or overlapped and selectable by tabs, for example.

FIG. 2C depicts circuitry 200 for a smart switch, according to some embodiments. Some embodiments may have fewer components than those shown in FIG. 2C, and other embodiments may have more components than those shown in FIG. 2C. One or more of the components shown may be mounted to or plugged into the integrated circuit board 220 of a smart switch.

In some implementations, a smart switch may comprise a processor 260 that is arranged to receive power from at least one power source (e.g., an AC/DC converter 280 and/or a rechargeable battery 284), received commands from a touch pad 262 (or a touch screen), and operate at least one relay 274. The processor 260 may include temporary and/or permanent digital memory. In some cases the smart switch may include one or more memory chips (not shown) having temporary and/or permanent digital memory, wherein the memory on the chips can be accessed by the processor 260. The converter 280 may include isolation and voltage or current limiters to protect the DC circuitry from power surges. An on-board charging circuit 282 may be included to maintain a charge on battery 284 and provide back-up power in the event of power failure. Battery 284 may comprise one or more rechargeable, button-cell batteries, or may comprise a pair of rechargeable, AAA size batteries. In some cases, the battery 284 may comprise cells or packs of other standard size and capacity batteries. In some implementations, the battery 284 may comprise a custom battery or cells or packs of custom size and capacity batteries. The battery 284 may provide power mainly for LED lighting 271 during a power outage, though may also provide power for logic operations during a power outage in some implementations. Power logic circuitry 286 may select power from the converter 280 during normal operation and from battery 284 during an AC power outage.

In some implementations, a battery 284 may be located in the touch-control assembly 102, and there may not be a battery located inside the wall-mount junction box. The battery 284 in the touch-control assembly may receive charge from the smart switch's on-board charging circuit 282 via a multi-pin connector, according to some embodiments.

According to some embodiments, the processor 260 may include a communication port that allows data to be received from or sent to a data transceiver 273. The data transceiver 273 may communicate with other devices via a wireless network link or a wired network link. The supported wireless network communication protocols may include but are not limited to Wi-Fi®, Bluetooth®, ZigBee®, Z-Wave®, and select Radio Frequencies (RF). The processor 260 may further include general-purpose input/output (GPIO) circuit and corresponding pins that are used to communicate with peripheral devices such as, but not limited to, sensors 264, light-emitting diode(s) (LED) 271, speaker 272, manual override buttons 267, and vibrator module (not shown). In some embodiments, one or more of the peripherals may be mounted in the wall-mount adapter 105 (referring to FIG. 1), though some peripherals may be mounted on the touch-control assembly 102 or integrated circuit board 220.

There may be additional GPIO circuitry and corresponding pins for control of AC power delivery that are arranged to interface with one or more TRIAC(s) or relay(s) 274. In some implementations, there may be GPIO pins to interface with a fan speed control and/or dimmer control. There may be isolation 275 (e.g., electro-optical isolation) between the GPIO pins for controlling AC power delivery and corresponding peripheral devices (e.g., relays, fan control, dimmer control).

In some implementations, a processor 260 may further include analog-to-digital (A/D) and/or digital-to-analog (D/A) ports through which the processor may communicate with and receive data from one or more peripheral devices. One example of a peripheral device that connects to an A/D port is a line sensor 292 that senses an amount of alternating current provided to a load. Data received from the line sensor 292 may be processed by the processor 260 and used to monitor and record energy consumption in a controlled circuit, for example.

The processor 260 may also receive data from a touch pad 262 (or touch screen), according to some embodiments. Data from the touch pad 262 is analyzed to determine a type of command issued to the processor, and to execute a predetermined function (e.g., dimming, fan speed adjustment, power off, etc.). According to some implementations, the touch pad 262 (or touch screen) may communicate with the processor over a dedicated port, or may communicate through an A/D port.

In some embodiments and referring again to FIG. 1, the touch-control assembly 102 may operate a smart switch when removed from the wall-mount adapter 105. In such embodiments, the smart switch circuitry 200 may include an additional processor 260 and additional transceiver 273, referring to FIG. 2C. For example, a first processor 260 and first transceiver 273 may be located on the integrated circuit board 220 in the wall-mount adapter, so that signals can be received and processed when the touch-control assembly 102 is removed from the wall-mount adapter. A second processor 260 (not shown in FIG. 2C) and a second transceiver 273 (not shown in FIG. 2C) may be located in the touch-control assembly 102, so that signals from the touch-control surface may be received, processed, and transmitted wirelessly to the first processor 260 in the wall-mount adapter.

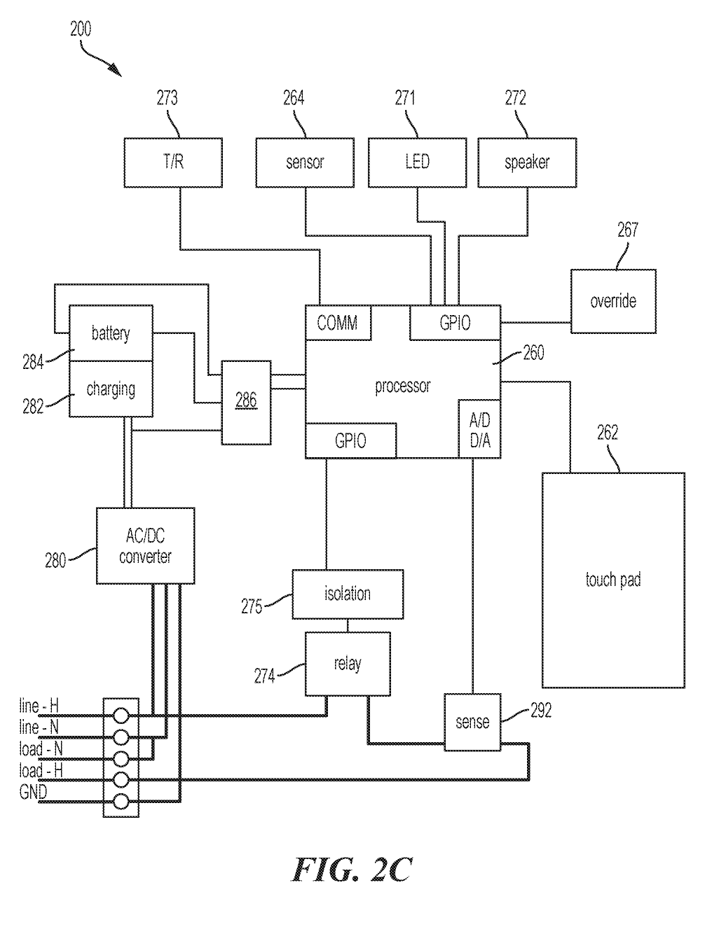

A plan view of an integrated circuit board 220 is depicted in FIG. 3, according to some embodiments. The integrated circuit board may include receiving ports 305 into which function-adding chips 310 may be plugged and removed to add or remove additional functionality to the smart switch 100. For example, a first function-adding chip 310a may plug into the integrated circuit board 220 via a mini USB plug or other connector, and add Wi-Fi® communication capability to the smart switch 100. A second function-adding chip 310b may plug into the integrated circuit board and add Bluetooth® communication capability to the smart switch. Additional function-adding chips may be plugged into the integrated circuit board to add features such as, but not limited to, ZigBee® functionality, Z-Wave® functionality, AM/FM radio functionality, and voice-recognition functionality.

A smart switch 100 may further include one or more buttons 320 on the integrated circuit board 220 or on the wall-mount adapter 105 that can be used to activate or deactivate one or more relays 230 located behind the integrated circuit board. For example, a first button 320 may be used to toggle a first relay on and off. A second button may be used to operate a second relay. A button 320 may be either a mechanical button, a capacitive button, or inductive touch-sensitive button. The buttons 320 may allow operation of the smart switch 100 when the touch-control assembly 102 has been removed from the smart switch.

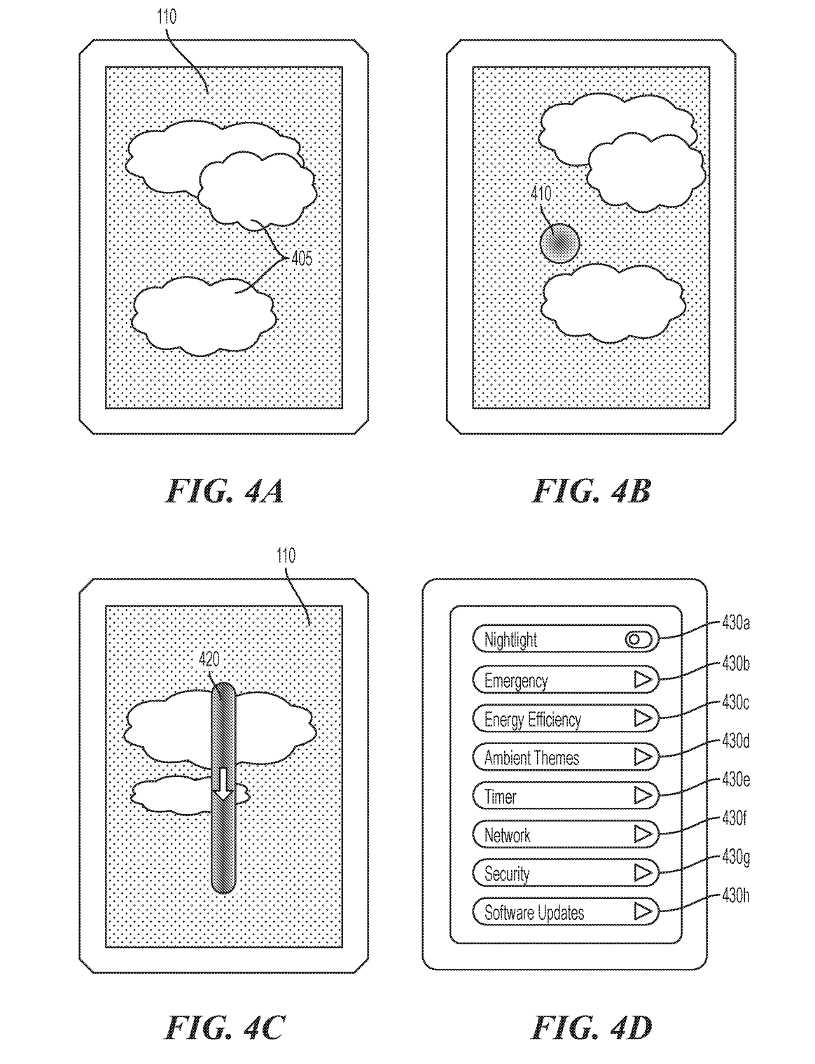

As described above, a smart switch 100 may include a touch screen for the touch-control surface 110 in some embodiments. FIG. 4A depicts a scene that may be displayed on a touch screen of a smart switch when the smart switch is in operation, according to some embodiments. In some embodiments, artwork 405 may be displayed on the touch screen when the smart switch 100 is in operation. Any suitable artwork may be displayed, such as scenery, images of people, images of cartoon characters, an artistic pattern, a pattern that matches or complements coloring within a room, historical quotes, videos, or animations. Such a scene may be provided by default, user defined, or automatically updated via consumer subscription to an online content channel.

In some embodiments, a smart switch 100 may be responsive to a user's touch sequences and/or traced patterns (sometimes referred to as gestures) made on the touch-control surface 110 when the smart switch is in operation. The switch may provide visual and/or audio and/or vibration feedback in response to a user's touch sequence and/or traced patterns. In some embodiments, the visual feedback may materialize as, for example, a visual artistic distortion effect of the background art image or color a user may have chosen, an animated water ripple, smoke, or pixelated effect. In some embodiments, the visual feedback may materialize as a visible trace on the screen, such as a paint-brush effect, for example.

Non-limiting examples of touch and traced patterns that may be applied to a touch-control surface are depicted in FIG. 4B and FIG. 4C. According to some embodiments, a temporary touch 410 on the touch screen that is displaying artwork 405 may be interpreted by a processor of the smart switch as a command to control power delivery to an electrical circuit within the building. For example, a user may touch the artwork for a duration that is less than a predetermined duration (e.g., less than about 1 second, or less than about 2 seconds, etc.) to turn lights on or off in a room. A processor of the smart switch may detect and analyze the touch on the touch-control surface (e.g., a single, stationary touch), determine its duration and/or sequence, and interpret the touch as a command to change the state of the relay 230.

As another example, a user may touch and slide one or more fingers downward on the touch screen as depicted in FIG. 4C. The resulting trace 420 may be detected and analyzed by a processor of the smart switch, and interpreted as a command to dim lighting within the room. The processor may then activate dimming circuitry of the smart switch 100 to reduce the amount of power delivered to the room lighting.

As another example, a user may draw a clockwise circle on the touch-control surface 110, and the processor may analyze and interpret data associated with the traced pattern as a command to temporarily lock control of the smart switch. A counterclockwise circle, a pattern difficult for young children to draw, may be recognized by the processor as a command to unlock control of the smart switch.

According to some embodiments, the processor 260 may execute machine-readable instructions that allow pattern recognition of traces made on the touch-control surface 110. For example, a trace made on the touch-control surface 110 may generate a stream of data that is sent to the processor 260. The received data may be analyzed for features (e.g., duration, linearity, amplitude, position, rotation, etc.) and the detected features compared against stored feature sets that correspond to previously traced patterns that have been associated with corresponding commands. Upon a match or near match of features, the processor may “recognize” the trace and execute the corresponding command.

As another example, a user may apply a single touch 410 to the touch-control surface 110, and hold their finger on the touch-control surface for a duration greater than a predetermined duration (e.g., greater than about 1 second, greater than about 2 seconds, etc.). A processor of the smart switch may detect the single, stationary touch 410, determine it has a prolonged duration, and display a context-sensitive user interface that is preprogrammed or user configured. The touch may be identified by the processor as a command to display a menu to access control options. The processor may then “fade out” the artwork 405 and “fade in” a menu to access control options, as depicted in FIG. 4D. In some embodiments, the touch pattern may be identified by the processor as a command to display a menu to access light control options and the processor may then fade out the artwork 405 and fade in a menu to access light control on/off and granular dimming options, (e.g., transforming the display to a control GUI as depicted in FIG. 4E). The artwork may be restored once the user completes entering commands via the GUI.

In some embodiments, a menu may include graphical, touch-sensitive buttons 430 that can be selected to access and/or configure different operational modes of the smart switch 100, as depicted in FIG. 4D. For example, the menu may include, but not be limited to, one or more of the following graphical buttons or corresponding icons: a “Nightlight” button 430a, an “Emergency” button 430b, an “Energy Efficiency” button 430c, an “Ambient Themes” button 430d, a “Timer” button 430e, a “Network” button 430f, a “Security” button 430g, and a “Software Updates” button 430h.

According to some embodiments where the smart switch 100 contains a light sensor configured to detect the brightness level of the ambient light, selection of a Nightlight button 430a (e.g., by touching the button) may be detected by a processor of the smart switch to enable or disable a nightlight feature. While enabled, a processor of the smart switch may automatically adjust a brightness of the touch screen, and/or one or more included LEDs in the smart switch to provide low-level lighting in a dimly lit ambient environment as a night light. In some embodiments, the smart switch may reduce or shut off its on-board lighting when the ambient light level exceeds a predetermined value. According to some embodiments, the nightlight operation may be based on a predetermined time schedule or a combination of ambient lighting and a predetermined time schedule. In some embodiments, selection of the Nightlight button (e.g., by tapping the button, swiping, or holding a finger on it for an extended time) may be detected by a processor of the smart switch. The processor may then present a GUI to the user for programming a schedule for the nightlight operation.

According to some embodiments, selection of an Emergency button 430b may be detected by a processor of the smart switch and interpreted as a command to call up a GUI that allows a user to enable or disable an emergency light feature (e.g., when the smart switch 100 contains a battery, or if emergency lighting is connected to and controlled by the smart switch). While emergency lighting is enabled, the smart switch may increase the brightness of the touch screen and/or turn on one or more on-board LEDs. In some implementations, a processor of the smart switch is configured to detect an AC electrical power outage and activate emergency lighting automatically. In some cases, the processor may be configured to detect, via an ambient lighting sensor, whether the ambient lighting is below a threshold value and only activate emergency lighting if the smart switch senses that ambient lighting is low. The emergency light may remain on until the AC power is restored or until the battery charge is consumed. The brightness of the touch screen and/or the state of the LED(s) may be restored to a previous state once power is restored.

According to some embodiments, a smart switch may be configured to connect automatically, or in response to commands input by a user, to a local or wide-area network via a wireless link as a registered client device, for example. The network may include a server that registers smart switches under unique identifiers and may associate the identifiers with user information, such as email address, phone number, etc and one or more client devices for the user (e.g., cell phone(s), work phone(s), office email address(es), etc.). In some implementations, the server may associate device commands with the identifiers, wherein a device command, when issued to a client device, causes the client device to execute a specific function (e.g., vibrate, make a sound, flash a light, display a message, ring and play an audio message).

In some implementations, a smart switch may be configured to identify an alert condition and issue an alert signal to a server and/or one or more mobile devices connected to a network that is accessible by the smart switch (e.g., a home network, office network, campus network, or wide-area network). The issued alert signal may be a coded signal that identifies the alert condition (e.g., power outage, smoke detected, low temperature, high temperature, etc.) and is recognizable by a smart switch server or other client device configured to receive the alert signal from the smart switch. The server may identify the issued alert and recognize a unique identifier for the smart switch that is transmitted with the alert signal. In response, the server may communicate with at least one client device that has been registered with the server by the user of the smart switch. The server may transmit data to the client device (or set of client devices) and cause the client device to execute an associated function corresponding to the issued alert (e.g., display the message “power outage” to a smart phone, automatically turn on a flashlight or vibrator application, or run another application). In this manner, a smart switch may automatically notify a user (located in the vicinity of the smart switch or remotely) of an emergency condition, or other conditions, that arise at the installation site of the smart switch.

According to some embodiments, a GUI of the smart switch may be configured to allow the user to pair the smart switch with a separate alarm or security system installed at a home or facility. Once paired, the alarm or security system may trigger the smart switch, regardless of a power outage, to strobe (turn on and off the touch screen or included LED(s)) at a predefined frequency and/or sound an audible alarm to alert the user in case of intrusion, smoke, or fire hazard, etc. In some embodiments, a smart switch located near an exit may be configured to help identify the location of safe exit paths from a building.

According to some implementations, selection of an Energy Efficiency button 430c may be detected by a processor of the smart switch 100 and interpreted as a command to call up a GUI that allows a user to enable energy savings and monitoring of power consumption features. According to some embodiments, the user may enable sleep mode of the smart switch (e.g., powering down the LCD touch screen) to conserve energy. While the sleep mode is enabled the switch may dim its touch screen after a predefined number of seconds of user inactivity thus decreasing its power consumption. The user may interrupt the sleep mode by touching the touch screen, waiving in front of the switch or pushing a button. In some embodiments where the smart switch 100 includes a sensor or a camera to detect motion, or is paired with an external motion detector, the user may configure the smart switch to automatically turn on a circuit (such as lighting) upon the detection via the sensor of a nearby moving (approaching/passing) object (human or other), and to turn off the circuit upon the lapsing of a user-defined time interval beyond the time of last motion detection. According to some embodiments where the smart switch 100 includes a power consumption meter, the user may enable the measurement and reporting of the switch's circuit power consumption to be viewed by the user on demand.

According to some embodiments, selection of an Ambient Themes button 430d may be detected by a processor of the smart switch 100 and interpreted as a command to call up a GUI that allows a user to list and select one or more of the smart switches connected to the same home or office network. The smart switches connected to a local-area network may communicate with each other via a transceiver 273 and provide a unique identifier for networked operation. A user may modify the operational settings of one or more smart switches in a local-area network, and may define smart-switch groups using the unique identifiers that include some or all of the smart switches in the local area network. Smart switches assigned to a group may be controlled simultaneously in a same way and from a single smart switch that may be designated as a master for the group, according to some embodiments. A user may save smart-switch settings to a user defined group or single smart switch, and create an ambient theme such as dining, TV watching, romantic, nighttime, office projection, office presentation, etc. Once a user turns on a theme, the normal operation of participating switches is interrupted and set to the settings stored for the theme, and restored when the theme is turned off.

In some embodiments where one or more switches contain or are paired with an external ambient light sensor, the GUI allows the user to enable the measurement of the brightness level of the ambient light and maintain it to a preconfigured level of intensity by automatically increasing the brightness of electric lighting as natural, ambient light conditions become dimmer. For example, a processor of the smart switch may increase brightness of one or more controlled lights as daylight wanes and may dim one or more controlled lights when daylight increases responsive to a sensed natural, ambient light level.

According to some embodiments, selection of the Timer button 430e may be detected by a processor of the smart switch 100 and interpreted as a command to call up a graphical user interface (GUI) that allows a user to program calendar dates, days of the week and times during the day at which lighting and/or other electrical circuits in one or more rooms as well as outside the building is (are) to turn on and off and/or the manner in which lighting is turned on or off. The GUI may further be used to select programmed or randomized activation/deactivation times when a user may be away from the building for extended periods of time, e.g., on vacation for several days or weeks. The GUI may further allow the user to program the manner in which the lights are turned on and off, e.g., abruptly, dimming to an off state over a user-defined or fixed duration of time, blinking and then turning off after a user-defined or fixed duration of time. In some embodiments, the GUI allows the user to enable a self-learning mode where the smart switch tracks the user's behavior and notes the days and times one or more controlled circuits is (are) turned on and off by the user, utilizes mathematical formulas to identify optimum days and times of day to operate the switch, and automatically operates the switch from there on unless interrupted by manual user intervention.

According to some embodiments, selection of the Network button 430f may be detected by a processor of the smart switch and interpreted as a command to display a GUI that allows the user to specify wireless network communication parameters for the smart switch 100. The switch may be configured to join or pair over a multitude of networks of different communication protocols such as Wi-Fi®, Z-wave® and ZigBee®, Bluetooth®, etc. The GUI may further be used to cause the smart switch 100 to connect to the World Wide Web or a local network, so that data may be retrieved from or communicated to a remote device over the Internet. For example, a network connection may be used to download machine-readable instructions for the smart switch 100 directly on the switch (e.g., to add or upgrade smart switch functionality) or indirectly from a connected mobile device, remotely monitor and control another smart switch, participate in ambient themes, transmit alarms, and/or be investigated via remote troubleshooting, according to various embodiments. In some cases, a network GUI displayed on a smart switch may be used to navigate, via a Web browser, to favorite internet sites of the user (e.g., to view news or listen to radio broadcasts).

In some implementations, selection of a Security button 430g may be detected by a processor of the smart switch 100 and interpreted as a command to present a GUI to the user that allows the user to define an access code that will later be recognized by the processor as a valid code to permit operation of one or more features of the smart switch 100. An access code may comprise an alpha-numeric sequence, or may comprise a touch or trace pattern on the touch-control surface 110. In some embodiments, the Security GUI may allow the user to limit the remote access to the smart switch to certain network protocols (e.g., Bluetooth® only). In some implementations, the Security GUI may allow the user to limit the type of network access from a smart switch (e.g., censor

Internet web access). In some implementations, the Security GUI may allow the user to limit control aspects of the smart switch for remote devices connected to the same home or office network. In some embodiments, the Security GUI may allow user to create and manage alarm messages on the smart switch 100 that may be transmitted to one or more network destinations (e.g., to a mobile device as SMS or email). A security GUI may also allow the user to define the types of events that would trigger such alarms including when a switch is or is not operating within a user defined time period (e.g., send alarm message if a certain switch is on after midnight, turns on or off, senses motion, or engages emergency alarm operation).

According to some embodiments, touch of the Software Updates button 430h may be detected by a processor of the smart switch 100 and interpreted as a command to call up a GUI that allows a user to identify and manage installation of software updates to the smart switch. For example, a user may turn on user notifications to alert the user to the availability of software updates for the smart switch directly on the switch, via a text message to a registered mobile device, or via an email message.

In some embodiments, selection of a Gesture button, not shown, may be detected by a processor of the smart switch 100 and interpreted as a command to learn touch and/or trace patterns that are provided by a user. The processor may display a GUI that allows the user to input a touch or trace pattern to the smart switch 100, and further define a command associated with the touch or trace pattern. For example, the user may input the downward trace pattern 420, as depicted in FIG. 4C, and define a light-dimming command (e.g., reduce power to lights by 15%, or reduce continuously until the trace is stopped) that will correspond to the trace pattern detected by the processor.

According to some embodiments and referring to FIG. 4E, a GUI may include touch-sensitive buttons 440a-440d that can be selected to control the operation of the smart switch 100. For example, a GUI may include, but not be limited to, an icon 440a depicting the type of circuit the switch is controlling (in this case a light). In some embodiments, the GUI may include a series of buttons 440b that allow the user to have visual and granular control over a brightness level of lighting. In other embodiments, the icon may depict a fan, and the GUI provide discrete control of fan speed. In some embodiments, the GUI may include an on/off icon 440c that, when touched, toggles a light or circuit on an off. The GUI may also present general menu buttons or icons 440d to allow the user to navigate to and operate other functionality.

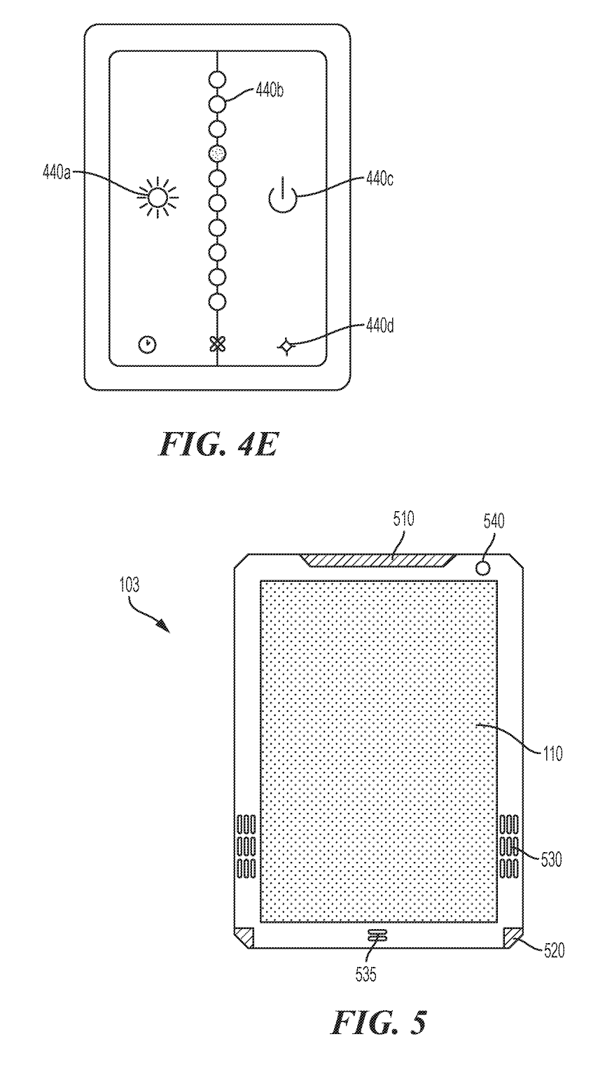

Another embodiment of a touch-control assembly 103 having a touch pad or touch screen is depicted in FIG. 5. In some embodiments, the touch-control assembly 103 may include one or more light-emitting diodes 510, 520 located on the touch-control assembly. A first LED 510 may comprise a high-brightness white LED that can be used as emergency lighting during a power outage, or as a flashlight when the touch-control assembly 103 is removed from the wall-mount adapter 105. Low-brightness LEDs 520 may also be included on the touch-control assembly 103, and may be used as nightlights according to some embodiments. Alternatively, a touch screen of a touch-control assembly may be used as both a flashlight and a nightlight, and LEDs 510, 520 may not be present.

In some cases, a touch-control assembly 103 may include speakers 530 and a microphone 535. Speakers may be used to play music, in some embodiments, audio feedback in response to a user's touch, sound an alarm in case of emergency, and/or to announce a status or location of the smart switch 103 for the visually impaired. A microphone, may be used to receive voice commands in some embodiments, as a room monitor in some embodiments, or for intercom functionality in some embodiments. For example, a microphone 535 may be used to monitor sounds from a sleeping infant small child within a room while a caregiver is outside the room. In some cases, a microphone may be used for room-to-room intercom communications.

Some embodiments of a touch-control assembly 103 may further include a camera 540. The camera may include a lens that is visible on the touch-control assembly and associated electronics (e.g., photodiode array, image-processing electronics) that may be mounted within the touch-control assembly. A camera 540 may be used to monitor activity within a room, in some embodiments. According to some implementations, a camera 540 may be used to sense movement in a room, and to activate lighting within a room responsive to the movement (e.g., turn lights on in a darkened room when the smart switch detects an individual entering the room).

In some implementations, certain components of a smart switch 100, such as LEDs, speakers, microphone, light sensor, motion sensor and camera may alternatively, or additionally, be included on the wall-mount adapter 105.

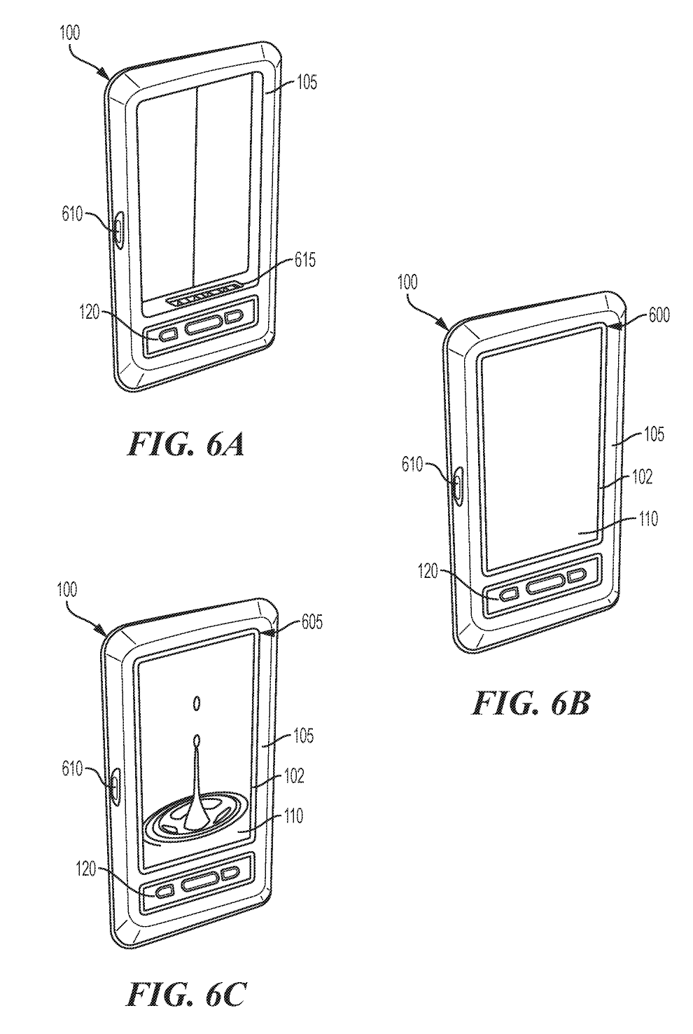

FIG. 6A through FIG. 6C illustrate an embodiment of a smart switch 100 that shows how a touch-control assembly 102 may be interchanged. The illustration in FIG. 6A shows a smart switch with the touch-control assembly removed. A multi-pin connector 615 may be visible in the wall-mount adapter 105 and provide electrical connections to the touch-control assembly when installed. In FIG. 6B, a touch pad 600 is shown inserted into the wall-mount adapter 105. In FIG. 6C, a touch screen 605 is shown inserted into the wall-mount adapter 105. According to some embodiments, a processor of the smart switch is configured to identify the type of touch-control assembly and configure the operation of the smart switch to be compatible with the touch-control assembly, so that additional changes to hardware are not needed to operate the smart switch. In some embodiments, the wall-mount adapter 105 may include press-release buttons 610 on one or more edges of the wall-mount adapter that are pressed to release the touch-control assembly. The press-release buttons 610 may prevent young children from removing the touch-control assembly.

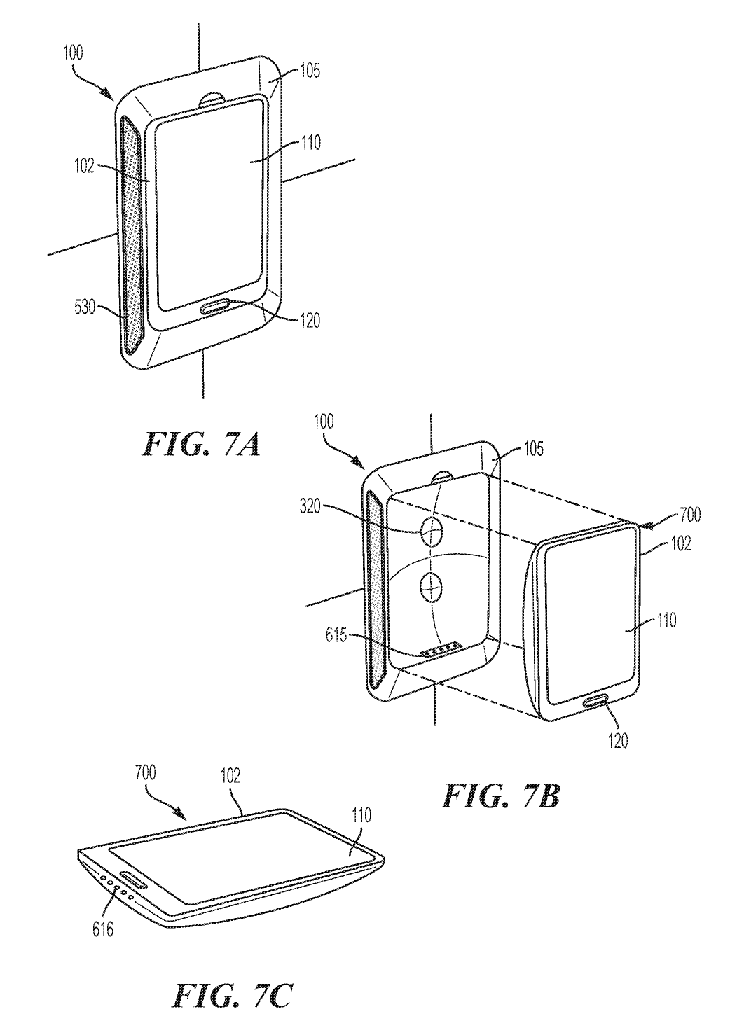

FIG. 7A through FIG. 7C depict an embodiment of a smart switch in which the touch-control assembly 102 has a curved shape so that it can be easily held in a user's hand. FIG. 7A shows the smart switch with the touch-control assembly inserted into the wall-mount adapter 105. FIG. 7B shows the touch-control assembly 102 removed from the wall-mount adapter. A pin connector 615 may be used to electrically connect the touch-control assembly to circuitry housed by the wall-mount adapter. FIG. 7C shows pins 616 at a base of the touch-control assembly 102 that may insert into the pin connector 615 in the wall-mount adapter. According to some embodiments, one or more magnets (not shown) may be used to help retain the touch-control assembly in the wall-mount adapter.

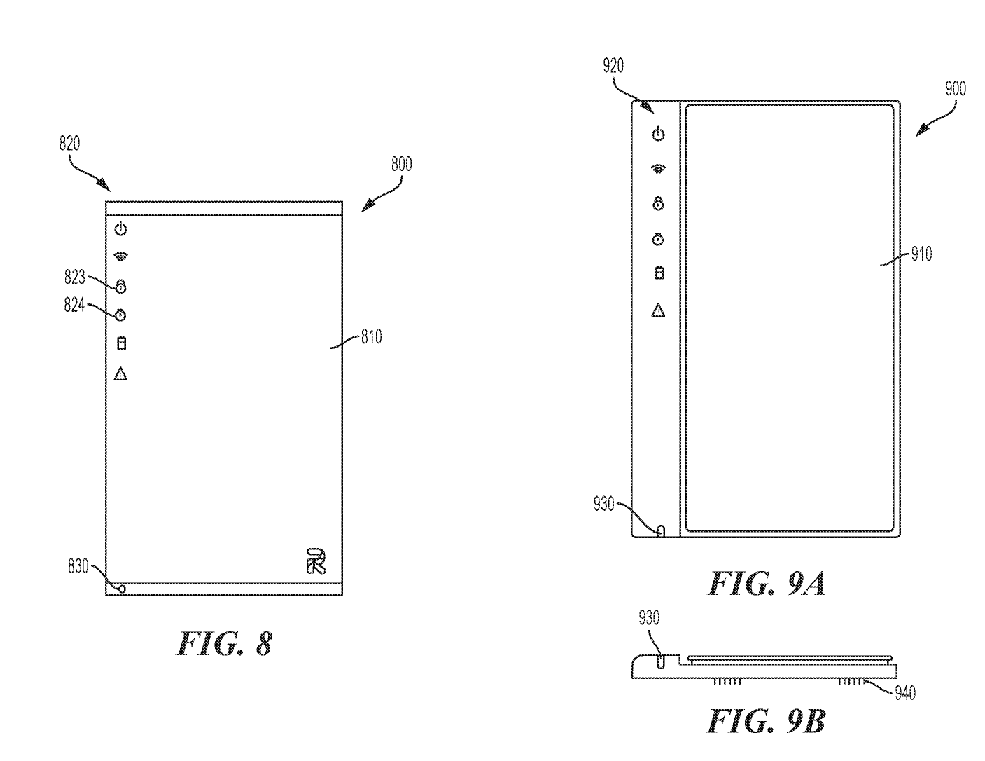

FIG. 8 depicts a touch-pad embodiment of a smart switch 800. In some cases, a touch-control assembly may comprise a touch pad permanently connected to and located behind a finished cover plate 810. The cover plate 810 may include status indicators 820 and an opening for an LED 830. The status indicators may illuminate or change color to indicate the status of a functional feature of the smart switch. For example, a “lock” indicator 823 may illuminate or change color to indicate that the smart switch is in a locked state (e.g., a user has drawn a circle on the cover plate 810 to lock controls of the smart switch). As another example, a “clock” indicator 824 may illuminate or change color to indicate that the smart switch is automatically operating to provide power to one or more loads according to a pre-programmed schedule.

The cover plate 810 may be formed from any suitable material (glass, plastic, carbon fiber, wood veneer, stone veneer, fabric or leather on a backing, etc.) and may be thin enough over the touch pad so that capacitive changes can be sensed by the touch pad. In some embodiments, the cover plate may have a thickness over the touchpad between 50 microns and 1 mm. The cover plate 810 may be manufactured and made available, with the attached touch-control assembly, in a variety of colors, patterns, shapes, and materials.

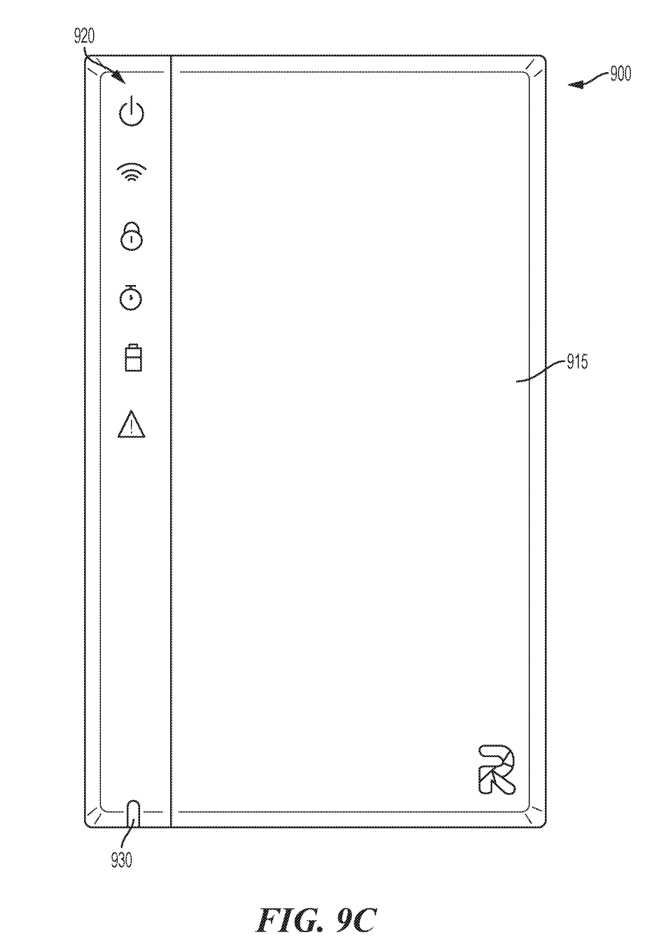

Some embodiments may include a removable and interchangeable cover and/or touch-control assembly, as indicated in FIG. 9A through FIG. 9C. FIG. 9A depicts a portion of smart switch 900 in which an interchangeable cover (shown in FIG. 9C) has been removed. The smart switch 900 may comprise a touch pad 910, status indicators 920, and an opening or transparent window for an LED 930. The touch pad 910 may mount on a wall-mount adapter 905 that includes the status indicators 920 and opening or window for the LED 930, according to some embodiments. In some cases, the touch pad 910 may not be removable from the wall-mount adapter, and instead, the wall-mount adapter and touch pad may be replaced as a single unit with a compatible touch pad or touch screen and wall-mount adapter.

FIG. 9B depicts an end-on or elevation view of a touch-control assembly and wall-mount adapter, according to some embodiments. There may be a plurality of pins 940 on a back side of a touch-control assembly that press into a connector in the wall-mount adapter or integrated circuit board of the smart switch. In some embodiments, the touch-control assembly and wall-mount adapter may have a low profile (e.g., between 1 mm and 5 mm), so that they do not protrude a large distance from the wall. A touch-control assembly comprising a touch screen may extend further from the wall. There may be an area around the touch pad 910 configured to receive a cover (e.g., there may be snaps or other retaining features that hold a cover in place over the touch pad 910.

In FIG. 9C, an interchangeable cover 915 (having a leather-like surface) is illustrated over the touch pad 910. The interchangeable cover 915 may snap on and pull off, so that a user can readily remove and replace covers. According to some embodiments, the interchangeable cover 915 may be thin enough over the touch pad 910 and/or made of a suitable material, so that capacitive changes can be sensed by the touch pad. For example, a cover 915 may be formed from any suitable material (glass, carbon fiber, plastic, wood veneer, stone veneer, fabric or leather on a backing, etc.). According to some embodiments, the thickness of a cover over the touch-control surface may be between 50 microns and 1 mm thick. A variety of different covers 915 may be manufactured and made available, as an interchangeable part, in a variety of colors, patterns, shapes, and materials.

In some embodiments, smart switches may be configured to communicate with each other within a building. For example, several smart switches may communicate over a Bluetooth® link, Wi-Fi® link, or any other suitable link if they are equipped with such communication functionality. When communicating in a network, one or more smart switches may be configured to detect the number and identity of smart switches within the network, and also detect each members' control configurations. A smart switch 100 that is configured to detect an identity and control configuration of another smart switch in a network may provide a GUI that allows a user to remotely control operation of one or more detected smart switches in a building. In this way, multiple smart switches may be operated remotely through a single smart switch 100.

A smart switch may operate according to a variety of methods. At a high level, a smart switch may operate in an “active” state or a “sleep” state. The sleep state may be a power-conserving state. For example, artwork may not be displayed or may be displayed on a dim setting in a sleep state. In some embodiments, a smart switch may still be responsive to a touch and/or trace pattern input in a sleep state.

Operation of a smart switch responsive to a user's touch or trace pattern may be as follows. Responsive to a touch or trace pattern input on the touch-control surface 110, the touch-control surface may generate touch data representative of the location and motion of the touch or trace pattern. The touch data may be transmitted to a processor of the smart switch and analyzed to determine features of the touch. The identified features may include, but not be limited to, location of touch on the touch-control surface, number of simultaneous touches, duration of touch or touches, direction and speed of motion associated with each touch, angular motion of each touch, etc. The identified features may then be compared with features in a data store (e.g., a look-up table) to find an approximate match. Fuzzy logic may be used to determine whether the identified features match to stored features. The stored features may be stored in association with different commands that are used to control operation of the smart switch. If a match is found, then the smart switch may execute the associated command (e.g., initiate sleep mode for turning off lights).

Although embodiments of a smart switch have been described primarily for residential homes and commercial facilities that typically use AC voltages, the smart switches may be used in marine, aircraft, and mobile-home (e.g., camper, RV, etc.,), and other settings in which DC or non-standard AC voltages may be used. In such settings, relays 230 may be selected for compatibility with the available voltage characteristics.

### Conclusion

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

The technology described herein may be embodied as a method, of which at least some acts have been described. The acts performed as part of the method may be ordered in any suitable way. Accordingly, embodiments may be constructed in which acts are performed in an order different than described, which may include performing some acts simultaneously, even though described as sequential acts in illustrative embodiments. Additionally, a method may include more acts than those described, in some embodiments, and fewer acts than those described in other embodiments.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

1. A switch for controlling power delivery to a first circuit, the switch comprising:
an integrated circuit board;
a first touch-control assembly having a touch-control surface;
a processor; and
a wall-mount adapter configured to connect the integrated circuit board and the first touch-control assembly to a junction box in which electrical connection is made to the first circuit, wherein the first touch-control assembly and the wall-mount adapter are configured for plug-and-play interchange of the first touch-control assembly with a different second touch-control assembly.

2. The switch of claim 1, wherein the first touch-control assembly is configured to operate the switch when removed from the wall-mount adapter.

3. (canceled)

4. The switch of claim 1, wherein the first touch-control assembly comprises a touch pad and the second touch-control assembly comprises a touch screen.

5. (canceled)

6. The switch of claim 1, wherein the first circuit is an AC circuit and the first touch-control assembly is configured to be operated as a switch for at least a second AC circuit in addition to the first circuit when mounted in a same junction box.

7. The switch of claim 1, further comprising an interchangeable cover that can be mounted over the touch-control surface and removed by a user.

8. (canceled)

9. The switch of claim 1, further comprising:
at least one relay connected to the integrated circuit board;
a rechargeable battery arranged to provide power to at least one component of the smart switch; and
a charging circuit for the rechargeable battery.

10. The switch of claim 1, wherein the integrated circuit board includes receptacles for removably plugging in function-adding chips.

11. The switch of claim 1, wherein the integrated circuit board includes receptacles for removably plugging in one or more relays for controlling at least the first circuit.

12. The switch of claim 1, wherein the touch-control surface comprises a touch pad or a touch screen.

13. The switch of claim 1, further comprising a transceiver for communicating data over a wireless or wired network link.

14. The switch of claim 13, further including machine-readable instructions that enable the processor to download and install updated versions of machine-readable instructions that control operation of the processor and switch functionality.

15. The switch of claim 13, further including machine-readable instructions that configure the switch to be controlled remotely by a mobile device, a computer device, and/or a security system.

16-20. (canceled)

21. The switch of claim 1, further including machine-readable instructions that adapt the processor to interpret touches or traces made on the touch-control surface as commands to operate the switch.

22-26. (canceled)

27. The switch of claim 21, wherein the touch-control surface is a touch screen and further including machine-readable instructions that adapt the processor to display a graphical user interface on the touch screen.

28. The switch of claim 1, further including machine-readable instructions that adapt the processor to track user interaction with the switch over a period of time and learn the user's behavior and to subsequently execute automated operation of the switch based on the learned user's behavior.

29. The switch of claim 1, further comprising a power-measurement circuit and machine-readable instructions configured to detect and report energy consumption of the first circuit.

30. The switch of claim 1, further comprising a light sensor and machine-readable instructions to detect ambient light level and increase or decrease power delivered to the circuit to maintain a user-defined level of ambient light.

31. The switch of claim 1, further including machine-readable instructions that adapt the processor to detect an alert condition and transmit an alert signal that identifies the alert condition to a server or directly to a mobile device.

32. The switch of claim 1, further including machine-readable instructions that adapt the processor to display a graphical user interface that allows a user to group operation of plural smart switches in a local area network.
